(19) United States
(12) Patent Application Publication
(10) Pub. No.: US 2006/0220701 A1
(43) Pub. Date: Oct. 5, 2006

(54) Input Circuit of a Semiconductor Device

(75) Inventor: Seong Hwi Song, Icheon-Shi (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyunggi-do (KR)

(21) Appl. No.: 11/275,465

(22) Filed: Jan. 6, 2006

(30) Foreign Application Priority Data
Mar. 29, 2005 (KR) 2005-26148

(51) Int. Cl. H03B 1/00

(52) U.S. Cl. 327/108

(57) ABSTRACT

A input circuit of a semiconductor device is disclosed. The input circuit may include a data receiver including a first comparator for comparing first input data with a predetermined reference voltage and outputting second input data according to the result of the comparison, a second comparator for receiving a data strobe signal at its non-inverting input terminal and an inverted signal of the data strobe signal at its inverting input terminal, and a third comparator for receiving the inverted signal of the data strobe signal at its non-inverting input terminal and the data strobe signal at its inverting input terminal. The input circuit may also include a first driver for buffering an output signal from the second comparator and outputting the buffered signal as a first input strobe signal, a second driver for buffering an output signal from the third comparator and outputting the buffered signal as a second input strobe signal, and a data detector for detecting and outputting the second input data synchronously with the first input strobe signal and the second input strobe signal.

### FIELD OF THE INVENTION

This patent relates to a input circuit of a semiconductor device, and more particularly to a input circuit of a semiconductor device in which first and second input strobe signals, used in the semiconductor device for the detection of external input data in synchronization with the rising and falling edges of a data strobe signal, are generated using independent drivers, respectively, thereby preventing occurrence of a skew between the input strobe signals and making the setup time and hold time of the detected input data constant.

### DESCRIPTION OF THE RELATED ART

Generally, in a semiconductor device, a data strobe signal and an input strobe signal generated using the data strobe signal are used for detection of external input data. Here, the strobe signal generally refers to a control signal for data transmission, which is a short pulse signal used for synchronization of data transmission while data is sent or received in a computer system. The data strobe signal is a kind of this strobe signal and is used to allow the input of data in synchronization with rising and falling edges thereof. The input strobe signal is generated using the data strobe signal and is used as a synchronous signal when the external input data is detected by a data detector.

FIG. 1 shows the configuration of a conventional input circuit of a semiconductor device, FIG. 2 is a waveform diagram of signals in a conventional input circuit, and FIG. 3 is a timing diagram of a data strobe signal, an input signal and synchronous signals for input data detection in a conventional input circuit. A description will hereinafter be given of a conventional input circuit with reference to these figures.

As shown in FIG. 1, a comparator 111 compares first input data DIN, which is external input data, with a predetermined reference voltage VREF and outputs second input data DIND according to the compared result. Here, the second input data DIND is generated as a result of the comparison between the first input data DIN and the reference voltage VREF, and assumes a high level when the first input data DIN is high in level and a low level when the first input data DIN is low in level.

A comparator 112 receives a data strobe signal DQS at its non-inverting input terminal and an inverted signal DQSB of the data strobe signal DQS at its inverting input terminal, compares the received signals with each other and outputs a generation base signal CP, which is a base signal for generation of a first input strobe signal CPR and second input strobe signal CPF, according to the comparison result. Because the comparator 112 receives the signals DQS and DQSB at its non-inverting input terminal and inverting input terminal and compares the received signals with each other to output the signal CP, as described above, the signal CP assumes a high level when the data strobe signal DQS is high in level and a low level when the data strobe signal DQS is low in level, as shown in FIG. 2.

Then, a driver 120 receives the signal CP and outputs the first input strobe signal CPR and second input strobe signal CPF. Here, the first input strobe signal CPR is generated by buffering the signal CP by inverters IV11 and IV12, and is used to allow reception of the first input data DIN corresponding to a rising edge of the data strobe signal DQS. The second input strobe signal CPF is generated by inverting/buffering the signal CP by an inverter IV13, and is used to allow reception of the first input data DIN corresponding to a falling edge of the data strobe signal DQS.

Finally, a data detector 130 is enabled by an enabling signal EN to detect the second input data DIND synchronously with rising edges of the first input strobe signal CPR and second input strobe signal CPF. The data detector 130 then supplies the detected input data IDIN to an internal circuit of the semiconductor device. That is, as shown in FIG. 2, the data detector 130 first detects and outputs the second input data DIND synchronously with the rising edge of the first input strobe signal CPR, and then detects and outputs the second input data DIND synchronously with the rising edge of the second input strobe signal CPF. This operation is performed for a period in which the enabling signal EN is enabled high in level.

However, the above-mentioned conventional input circuit of the semiconductor device has a disadvantage in that the setup and hold time of the detected input data cannot be kept constantly due to a skew between the first input strobe signal CPR and the second input strobe signal CPF. In detail, in the conventional input circuit, the driver 120 uses only one generation base signal CP to generate the first input strobe signal CPR and the second input strobe signal CPF. For this reason, the inverter IV11 and inverter IV 12 for the generation of the first input strobe signal CPR and the inverter IV13 for the generation of the second input strobe signal CPF are not completely independently operated, but interfere with each other, thereby causing a skew to occur between the first input strobe signal CPR and the second input strobe signal CPF. The inter-signal skew affects a data setup/hold time, resulting in a difference between the setup time tSe/hold time tH1 of the first data detected depending on the first input strobe signal CPR and the setup time tS2/hold time tH2 of the second data detected depending on the second input strobe signal CPF, as shown in FIG. 3.

### SUMMARY OF THE INVENTION

An input circuit of a semiconductor device is capable of preventing a skew from occurring between first and second input strobe signals, used in the semiconductor device for detection of external input data in synchronization with the rising and falling edges of a data strobe signal, and making the setup and hold time of the detected input data constant. A Dual DQS Receiver may include a second receiver for receiving a data strobe signal at its non-inverting input terminal and an inverted signal of the data strobe signal at its inverting input terminal, and a third receiver for receiving the inverted signal of the data strobe signal at its non-inverting input terminal and the data strobe signal at its inverting input terminal.

An input circuit of a semiconductor device may include a data receiver including a first comparator for comparing the first input data with a predetermined reference voltage and outputting the second input data according to the results of the comparison, a second comparator for receiving a data strobe signal at its non-inverting input terminal and an inverted signal of the data strobe signal at its inverting input terminal, and a third comparator for receiving the inverted signal of the data strobe signal at its non-inverting input terminal and the data strobe signal at its inverting input terminal; a first driver for buffering an output signal from the second comparator and outputting the buffered signal as a first input strobe signal; a second driver for buffering an output signal from the third comparator and outputting the buffered signal as a second input strobe signal; and a data detector for detecting and outputting the second input data synchronously with the first input strobe signal and the second input strobe signal.

Preferably, the first driver includes a first inverter and a second inverter, and the second driver includes a third inverter and a fourth inverter.

The first comparator may receive the first input data at its non-inverting input terminal and the reference voltage at its inverting input terminal.

An input circuit of a semiconductor device may include a data receiver including a first receiver for receiving first input data and a predetermined reference voltage and outputting second input data, a second receiver for receiving a data strobe signal at its non-inverting input terminal and an inverted signal of the data strobe signal at its inverting input terminal, and a third receiver for receiving the inverted signal of the data strobe signal at its non-inverting input terminal and the data strobe signal at its inverting input terminal; a first driver for buffering an output signal from the second receiver and outputting the buffered signal as a first input strobe signal; a second driver for buffering an output signal from the third receiver and outputting the buffered signal as a second input strobe signal; and a data detector for detecting and outputting the second input data synchronously with the first input strobe signal and the second input strobe signal.

Preferably, the first receiver receives the first input data at its non-inverting input terminal and the reference voltage at its inverting input terminal.

An input circuit of a semiconductor device may include a data receiver for receiving a first input data and a predetermined reference voltage and outputting second input data; and Dual DQS Receiver for receiving a data strobe signal and an invertered data strobe signal respectively.

Preferably, the Dual DQS Receiver may include a second receiver for receiving a data strobe signal at its non-inverting input terminal and an inverted signal of the data strobe signal at its inverting input terminal; and a third receiver for receiving the inverted signal of the data strobe signal at its non-inverting input terminal and the data strobe signal at its inverting input terminal.

Preferably, the input circuit may include a first driver for buffering an output signal from the second receiver and outputting the buffered signal as a first input strobe signal; a second driver for buffering an output signal from the third receiver and outputting the buffered signal as a second input strobe signal; and a data detector for detecting and outputting the second input data synchronously with the first input strobe signal and the second input strobe signal.

### BRIEF DESCRIPTION OF THE DRAWINGS

Features and advantages of the present invention will be more clearly understood from the following detailed description taken in conjunction with the accompanying drawings, in which:

FIG. 1 is a circuit diagram showing the configuration of a conventional input circuit of a semiconductor device;

FIG. 2 is a waveform diagram of signals in the conventional input circuit;

FIG. 3 is a timing diagram of a data strobe signal, an input signal and synchronous signals for input data detection in the conventional input circuit;

FIG. 4 is a circuit diagram showing the configuration of a input circuit of a semiconductor device according to the present invention;

FIG. 5 is a waveform diagram of signals in the input circuit according to the present invention; and

FIG. 6 is a timing diagram of a data strobe signal, an input signal and synhronous signals for input data detection in the input circuit according to the present invention.

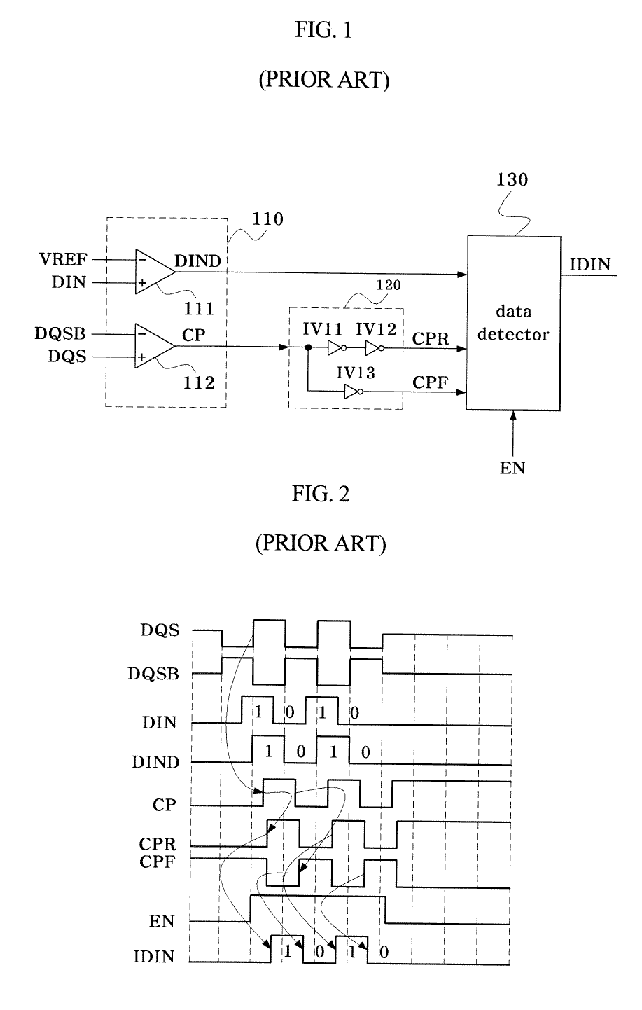

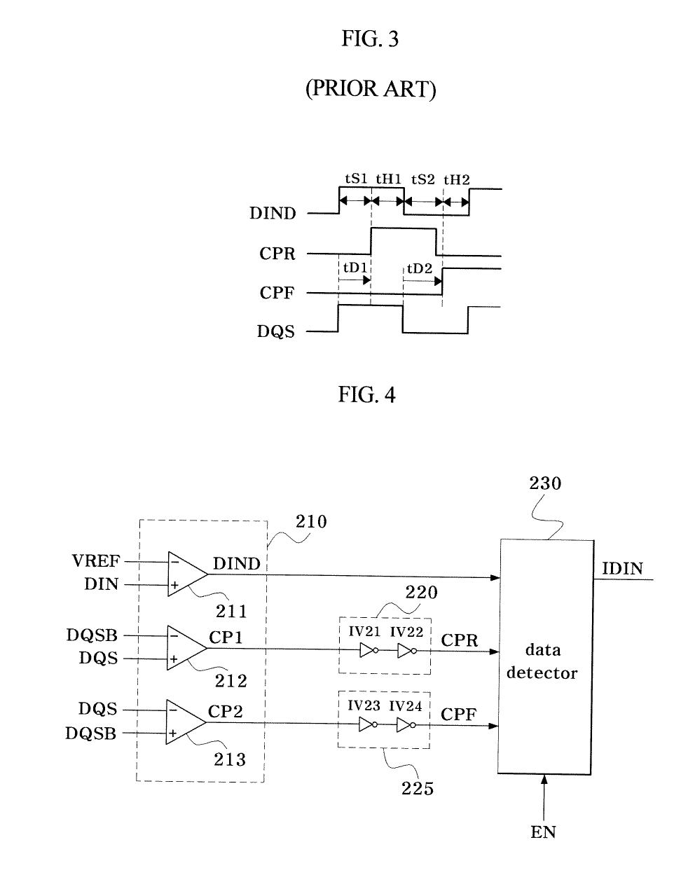

### DESCRIPTION OF THE PREFERRED EMBODIMENTS

Reference will now be made in detail to the preferred embodiments of the present invention, examples of which are illustrated in the accompanying drawings, wherein like reference numerals refer to like elements throughout. The embodiments are described below to explain the present invention by referring to the figures.

FIG. 4 shows the configuration of a input circuit of a semiconductor device according to the present invention. The present invention will hereinafter be described with reference to this figure.

As shown in FIG. 4, the input circuit according to the present invention comprises a data receiver 210 including a first comparator 211 for comparing first input data DIN with a predetermined reference voltage VREF and outputting second input data DIND according to the comparison result, a second comparator 212 for receiving a data strobe signal DQS at its non-inverting input terminal and an inverted signal DQSB of the data strobe signal DQS at its inverting input terminal, and a third comparator 213 for receiving the inverted signal DQSB of the data strobe signal DQS at its non-inverting input terminal and the data strobe signal DQS at its inverting input terminal. The input circuit according to the present invention further comprises a first driver 220 for buffering an output signal CP1 from the second comparator 212 and outputting the buffered signal as a first input strobe signal CPR, a second driver 225 for buffering an output signal CP2 from the third comparator 213 and outputting the buffered signal as a second input strobe signal CPF, and a data detector 230 for detecting and outputting the second input data DIND synchronously with the first input strobe signal CPR and the second input strobe signal CPF.

The first driver 220 includes an inverter IV21 and an inverter IV22, and the second driver 225 includes an inverter IV23 and an inverter IV24.

The operation of the input circuit with the above-stated configuration according to the present invention will hereinafter be described in detail with reference to FIGS. 4 to 6.

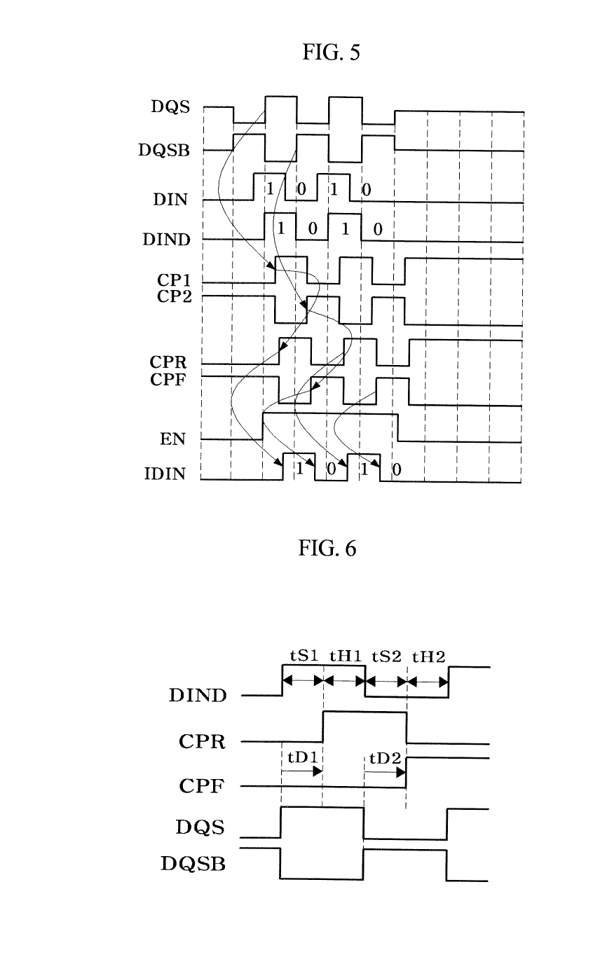

As shown in FIG. 4, the comparator 211 compares the first input data DIN, which is external input data, with the predetermined reference voltage VREF and outputs the second input data DIND according to the comparison result. Here, the second input data DIND is generated as a result of the comparison between the first input data DIN and the reference voltage VREF, and assumes a high level when the first input data DIN is high in level and a low level when the first input data DIN is low in level, as shown in FIG. 5.

The comparator 212 receives the data strobe signal DQS at its non-inverting input terminal and the inverted signal DQSB of the data strobe signal DQS at its inverting input terminal, compares the received signals with each other and outputs a generation base signal CP1, which is a base signal for generation of the first input strobe signal CPR, according to the comparison result. Because the comparator 212 receives the signals DQS and DQSB at its non-inverting input terminal and inverting input terminal and compares the received signals with each other to output the signal CP1, as described above, the signal CP1 assumes a high level when the data strobe signal DQS is high in level and a low level when the data strobe signal DQS is low in level, as shown in FIG. 5.

Then, the driver 220 receives the signal CP1 and outputs the first input strobe signal CPR. Here, the first input strobe signal CPR is generated by buffering the signal CP1 by the inverters IV21 and IV22, and is used to allow reception of the first input data DIN corresponding to a rising edge of the data strobe signal DQS.

Meanwhile, the comparator 213 receives the inverted signal DQSB of the data strobe signal DQS at its non-inverting input terminal and the data strobe signal DQS at its inverting input terminal, compares the received signals with each other and outputs a generation base signal CP2, which is a base signal for generation of the second input strobe signal CPF, according to the comparison result. Since the comparator 213 receives the signals DQSB and DQS at its non-inverting input terminal and inverting input terminal and compares the received signals with each other to output the signal CP2, as described above, the signal CP2 assumes a high level when the data strobe signal DQS is low in level and a low level when the data strobe signal DQS is high in level, as shown in FIG. 5.

Then, the driver 225 receives the signal CP2 and outputs the second input strobe signal CPF. Here, the second input strobe signal CPF is generated by buffering the signal CP2 by the inverters IV23 and IV24, and is used to allow reception of the first input data DIN corresponding to a falling edge of the data strobe signal DQS.

Finally, the data detector 230 is enabled by an enabling signal EN to detect the second input data DIND synchronously with rising edges of the first input strobe signal CPR and second input strobe signal CPF. The data detector 230 then supplies the detected input data IDIN to an internal circuit of the semiconductor device. That is, as shown in FIG. 5, the data detector 230 first detects and outputs the second input data DIND synchronously with the rising edge of the first input strobe signal CPR, and then detects and outputs the second input data DIND synchronously with the rising edge of the second input strobe signal CPF. This operation is performed for a period in which the enabling signal EN is enabled to a high level.

At this time, according to the present invention, no skew occurs between the first input strobe signal CPR and the second input strobe signal CPF, so that a setup time and hold time of the detected input data can be constantly secured, differently from the conventional input circuit. In detail, in the present input circuit, the separate generation base signals CP1 and CP2 are used for the generation of the first input strobe signal CPR and the second input strobe signal CPF, respectively. In addition, the first input strobe signal CPR is generated using the driver 220 including the inverter IV21 and inverter IV22, and the second input strobe signal CPF is generated using the driver 225 including the inverter IV23 and inverter IV24.

Therefore, no skew occurs between the first input strobe signal CPR and the second input strobe signal CPF by generating the first input strobe signal CPR and the second input strobe signal CPF using the separate generation base signals CP 1 and CP2 and the separate drivers 220 and 225, respectively. This occurrence of no inter-signal skew results in little difference between the setup time tS1/hold time tH1 of the first data detected depending on the first input strobe signal CPR and the setup time tS2/hold time tH2 of the second data detected depending on the second input strobe signal CPF, as shown in FIG. 6. In conclusion, according to the present invention, the setup and hold time of the detected input data can be secured in a constant manner by preventing a skew from occurring between the input strobe signals.

As apparent from the above description, the present invention provides a input circuit of a semiconductor device in which first and second input strobe signals, used in the semiconductor device for detection of external input data in synchronization with the rising and falling edges of a data strobe signal, are generated using independent drivers, respectively, thereby preventing occurrence of a skew between the input strobe signals and making a setup time and hold time of the detected input data constant.

Although the preferred embodiments of the present invention have been disclosed for illustrative purposes, those skilled in the art will appreciate that various modifications, additions and substitutions are possible, without departing from the scope and spirit of the invention as disclosed in the accompanying claims

What is claimed is:

1. A input circuit of a semiconductor device comprising:
a data receiver including a first comparator for comparing first input data with a predetermined reference voltage and outputting second input data according to the result of the comparison, a second comparator for receiving a data strobe signal at a non-inverting input terminal and an inverted signal of the data strobe signal at an inverting input terminal, and a third comparator for receiving the inverted signal of the data strobe signal at a non-inverting input terminal and the data strobe signal at an inverting input terminal;
a first driver for buffering an output signal from the second comparator and outputting the buffered signal as a first input strobe signal;
a second driver for buffering an output signal from the third comparator and outputting the buffered signal as a second input strobe signal; and
a data detector for detecting and outputting the second input data synchronously with the first input strobe signal and the second input strobe signal.

2. The input circuit as set forth in claim 1, wherein the first driver includes a first inverter and a second inverter, and the second driver includes a third inverter and a fourth inverter.

3. The input circuit as set forth in claim 1, wherein the first comparator receives the first input data at its non-inverting input terminal and the reference voltage at its inverting input terminal.

4. A input circuit of a semiconductor device comprising:
a data receiver including a first receiver for receiving first input data and a predetermined reference voltage and outputting second input data, a second receiver for receiving a data strobe signal at a non-inverting input terminal and an inverted signal of the data strobe signal at an inverting input terminal, and a third receiver for receiving the inverted signal of the data strobe signal at a non-inverting input terminal and the data strobe signal at an inverting input terminal.

5. The input circuit as set forth in claim 4, wherein the first driver includes a first inverter and a second inverter, and the second driver includes a third inverter and a fourth inverter.

6. The input circuit as set forth in claim 4, wherein the first receiver receives the first input data at its non-inverting input terminal and the reference voltage at its inverting input terminal.

7. A input circuit of a semiconductor device comprising:
a data receiver for receiving a first input data and a predetermined reference voltage and outputting second input data;
a Dual DQS Receiver for receiving a data strobe signal and an invertered data strobe signal respectively; and
a first driver for buffering an output signal from the Dual DQS Receiver and outputting the buffered signal as a first input strobe signal;
a second driver for buffering an output signal from the Dual DQS Receiver and outputting the buffered signal as a second input strobe signal; and
a data detector for detecting and outputting the second input data synchronously with the first input strobe signal and the second input strobe signal.

8. The input circuit as set forth in claim 7, wherein the Dual DQS Receiver comprises:
a second receiver for receiving the data strobe signal at a non-inverting input terminal and an inverted signal of the data strobe signal at an inverting input terminal; and
a third receiver for receiving the inverted signal of the data strobe signal at a non-inverting input terminal and the data strobe signal at an inverting input terminal.

9. The input circuit as set forth in claim 7, further comprising a first driver for buffering an output signal from the second receiver and outputting the buffered signal as a first input strobe signal;
a second driver for buffering an output signal from the third receiver and outputting the buffered signal as a second input strobe signal; and
a data detector for detecting and outputting the second input data synchronously with the first input strobe signal and the second input strobe signal.

10. The input circuit as set forth in claim 9, wherein the first driver includes a first inverter and a second inverter, and the second driver includes a third inverter and a fourth inverter.

11. The input circuit as set forth in claim 7, wherein the first receiver receives the first input data at its non-inverting input terminal and the reference voltage at its inverting input terminal.
